(19) United States
(12) Patent Application Publication
(10) Pub. No.: US 2015/0017832 A1
(43) Pub. Date: Jan. 15, 2015

(54) ELECTRICAL CONNECTOR

(71) Applicant: KONINKLIJKE PHILIPS N.V., EINDHOVEN (NL)

(72) Inventors: Maurice Herman Johan Draaijer, Ittervoort (NL); Bozena Erdmann, Aachen (DE); Michael Alex Van Hartskamp, Eindhoven (NL); Matthias Wendt, Wurselen (DE); Manuel Eduardo Alarcon-Rivero, Delft (NL)

(73) Assignee: KONINKLIJKE PHILIPS N.V., EINDHOVEN (NL)

(21) Appl. No.: 14/368,838

(22) PCT Filed: Dec. 19, 2012
(86) PCT No.: PCT/IB2012/057470

§ 371 Date: Jun. 26, 2014

Related U.S. Application Data
(60) Provisional application No. 61/580,414, filed on Dec. 27, 2011.

(51) Int. Cl. H01R 13/641; G01R 21/06

(52) U.S. Cl. CPC H01R 13/641; G01R 21/06
USPC 439/488

(57) ABSTRACT

The invention relates to an electrical connector for connecting an electrical device to an electrical conductor (3) for powering the electrical device (9) with DC voltage. The electrical connector (1) comprises an arrangement information providing unit for determining arrangement information being information about the arrangement of the electrical connector on the electrical conductor and an indicator (7) for indicating the provided arrangement information Since the arrangement information is provided and indicated, a user like an installer can easily see how the respective electrical connector is arranged on the electrical conductor, in particular, with respect to other electrical connectors. Specifically, if several electrical connectors are present, arrangement information can be provided for the several electrical connectors. This allows the user to easily obtain an overview of components of a DC power distribution system.

### FIELD OF THE INVENTION

The invention relates to an electrical connector for connecting an electrical device to an electrical conductor for powering the electrical device with direct current (DC) voltage. The invention relates further to a feeding connector for connecting an electrical conductor with a DC voltage source for feeding the electrical conductor with DC voltage.

### BACKGROUND OF THE INVENTION

A low voltage DC power distribution system is known from the EMerge standard. The DC power distribution system can comprise power rails to which many electrical devices, i.e. electrical loads, like lighting fixtures can be attached by using corresponding electrical connectors. It is often difficult to maintain an overview, i.e. to keep track of all components of the DC power distribution system.

### SUMMARY OF THE INVENTION

It is an object of the present invention to provide an electrical connector for connecting an electrical device to an electrical conductor for powering the electrical device with DC voltage, which allows a user to easily obtain an overview of components of a DC power distribution system.

In a first aspect of the present invention an electrical connector for connecting an electrical device to an electrical conductor for powering the electrical device with DC voltage is presented, wherein the electrical connector comprises:

an arrangement information providing unit for determining arrangement information being information about the arrangement of the electrical connector on the electrical conductor,

an indicator for indicating the provided arrangement information.

Since the arrangement information is provided and indicated, a user like an installer can easily see how the respective electrical connector is arranged on the electrical conductor, in particular, with respect to other electrical connectors. Specifically, if several electrical connectors are present, arrangement information can be provided for the several electrical connectors. This allows the user to easily obtain an overview of components of a DC power distribution system.

The electrical conductor is preferentially a power rail, which could also be called bus bar, and the electrical device is, for example, a lamp like a fluorescent lamp, a light emitting diode, et cetera.

After the arrangement information providing unit has provided the arrangement information, the indicator can indicate the arrangement information, for example, by acoustical or optical signals, or the indicator can report it over a communication interface like powerline communication (PLC), visual light communication (VLC), wireless communication, for instance, BACnet, KNX, 802.15.4/ZigBee, 802.15.4/6LoWPAN, 802.11/IP, et cetera.

It is preferred that the arrangement information providing unit is adapted to provide the location of the electrical connector on the electrical conductor as the arrangement information. It is further preferred that the arrangement information providing unit is adapted to provide commissioning information as the arrangement information. The commissioning information can include a number assigned to the electrical connector. The number may be regarded as being a commissioning number preferentially indicating the position of the respective electrical connector on the electrical conductor in a sequence of electrical connectors. For instance, the number can indicate that the respective electrical connector is at the sixth position in a sequence of twelve electrical connectors.

The arrangement information providing unit can also be adapted to determine a power loss and to provide the arrangement information based on the determined power loss. It is preferred that, if power losses are larger than a predefined threshold, the arrangement information indicates that the electrical connector should be moved towards a feeding connector connecting the electrical conductor with a DC voltage source. Thus, the indicator can reveal information like this load, i.e. this electrical device, will introduce a lot of losses in the electrical conductor, move it towards the feeding connector, in order to reduce the losses by decreasing the distance to the feeding connector.

The arrangement information providing unit is preferentially an arrangement information determining unit for determining the arrangement information. It can be a correspondingly adapted electrical circuit.

The arrangement information providing unit can be adapted to emit an acoustical signal and measure the time/strength of the response signals, whereby the response signals are either reflections caused by the end of the electrical conductor, in particular, of the bus bar, or acoustical signals actively generated by another electrical or feeding connector on the electrical conductor. The differentiation between the reflections from the end of the electrical conductor and the reflection from another electrical or feeding connector can be done by the arrangement providing unit by estimating the strength of the received signal and/or by using another frequency for the response signal. Furthermore, different frequencies could be used by different connectors, for example, depending on their type or role, for instance, load connector versus power connector/feed, and/or depending on their location on the electrical conductor. Some or all connectors may participate, for instance, only the closest connector to the newly added connector, only the feed connector, all connectors according to a given timing and order. The time and/or strength of the response signals can directly be related to the respective distances, thereby allowing the arrangement providing unit to determine the location of the current electrical connector on the electrical conductor and further arrangement information like the position of the current electrical connector within a sequence of electrical connectors. Thus, in an embodiment the arrangement information providing unit counts the responses and measures the times of their arrival and thus determines the number of other devices on the same electrical conductor and its own respective position.

In particular, the arrangement information providing unit can be adapted to determine the distance to the ends of the electrical conductor by receiving the reflected original acoustical signal and to determine the distance to the feeding connector, for instance, by receiving a repeated signal at a defined frequency from the feeding connector. This information, augmented by analogous information for other connectors on the same electrical conductor, which may be received from the other connectors via communications means or which may be determined by the current electrical connector, can subsequently be used by the arrangement information providing unit to determine the order of connectors on the electrical conductor. This determination of the arrangement information can also be performed by another unit, in particular, on the same or another electrical conductor, like a corresponding unit of the feeding connector, a handheld unit et cetera, and sent to the arrangement information providing unit, wherein the arrangement information providing unit can receive the arrangement information and the indicator can indicate this information.

The arrangement information providing unit can also be adapted to determine the distance to, for instance, an end of the electrical conductor and to sent this distance together with an unique identifier to another unit gathering corresponding distance information and respective unique identifiers from all other electrical connectors on the electrical conductor. This other unit can then use this distance information and the identifiers for determining the sequence of the electrical conductors on the electrical conductor, wherein to each electrical conductor a corresponding position within the sequence can be sent. This position is then received by the respective arrangement information providing unit and indicated by the indicator. The other unit gathering the information can be regarded as being a controller unit located in, for instance, in the DC voltage source, the feeding connector, or another device.

The power losses can be determined by using different techniques, which may be performed by the arrangement information providing unit or by an additional unit, which sends the power losses to the arrangement information providing unit. For instance, the voltage can be measured at multiple locations on the electrical conductor, for instance, at the feeding connector and at the electrical connector. For example, the feeding connector can measure the voltage at the feeding connector and the electrical connector can measure the voltage at the electrical connector, wherein the feeding connector can send the measured voltage to the electrical connector, in order to allow the arrangement information providing unit to determine the power losses associated with the actual location of the electrical connector. Also the current through the electrical connector can be measured for determining the power losses.

The arrangement information providing unit can be adapted to receive the arrangement information or to receive information, which is usable by the arrangement information providing unit for determining the arrangement information, over a wired or wireless data connection. For instance, the arrangement information providing unit can be adapted to receive commissioning number information from a feeding connector for connecting the electrical conductor with a DC voltage source for feeding the electrical conductor with the DC voltage.

It is also preferred that the electrical connector comprises a power supply for supplying power to the arrangement information providing unit and the indicator. The power supply is, for instance, a battery, a capacitor, et cetera. This allows the electrical connector to be operated, even if the electrical conductor is in a 0 V condition.

The electrical connector can comprise a cable for electrically connecting the electrical device to the electrical conductor, or it can be integrated into the electrical device. In particular, the electrical connector can be integrated into a housing of the electrical device. This allows directly connecting the electrical device to the electrical conductor, without using a cable for this connection.

In a preferred embodiment, the electrical connector comprises an input unit for allowing a user to input a request for providing and indicating the arrangement information. The input unit comprises, for instance, at least one of a push button, a dip switch, a slider, et cetera, wherein the electrical connector is adapted to provide, in particular, determine, and indicate the arrangement information, if, for example, the user presses the push button.

It is further preferred that the electrical connector comprises:

an assignments providing unit for providing assignments between a) at least one of determination procedures for determining arrangement information and indication procedures for indicating arrangement information and b) conditions, and

a condition providing unit for providing an actual condition,

wherein at least one of the arrangement information providing unit and the indicator are adapted to perform a determination procedure and an indication procedure, respectively, in accordance with the provided actual condition and the provided assignments.

The assignments providing unit can be a storing unit in which predefined assignments are stored already, or a receiving unit for receiving the assignments via a wired or wireless data connection. The condition providing unit can be a measuring unit for measuring the respective actual condition. The condition is, for example, an overload condition at the electrical conductor to which the electrical connector is connected. This allows the electrical connector to indicate arrangement information, only if the arrangement information is really relevant. The assignments can also be defined by other means like timing.

The indicator is preferentially adapted to optically and/or acoustically indicate the arrangement information. For instance, the indicator can comprise one or several light emitting diodes for indicating the arrangement information by using colors. In particular, a blinking can be used for indicating the position of the current electrical connector within a sequence of electrical connectors on the electrical conductor. The number of blinking signals can indicate the number counted from the feeding connector, or the position within the sequence can be indicated by using, for instance, green blinking for numbering information, long blinks for left, short blinks for right, i.e. it can be indicated that, for example, on the left side of the current electrical connector are five electrical connectors and on the right side are six electrical connectors such that the present electrical connector is at the sixth position out of twelve. For indicating whether the electrical connector should be moved towards the feeding connector a light in a certain color can be shown. For instance, a yellow blinking light can indicate that the electrical connector should be moved, wherein the faster the blinking the more losses. Also other colors, blinking schemes, intuitive signals like a running light emitting diode pattern with a running light emitting diode dot “running” in the direction in which the electrical connector should be moved for reducing losses, et cetera can be used for indicating the arrangement information.

In a further aspect of the present invention an electrical device to be electrically connected with an electrical conductor to be powered by DC voltage is presented, wherein the electrical device comprises the electrical connector as defined in claim 1.

In a further aspect of the present invention a feeding connector for connecting an electrical conductor with a DC voltage source for feeding the electrical conductor with DC voltage is presented, wherein the feeding connector comprises an arrangement determining unit for determining arrangement information for determining information about an arrangement of electrical connectors connected to the electrical conductor and a sending unit for sending the arrangement information to an electrical connector for allowing the electrical connector to indicate the arrangement information.

The arrangement determining unit can be adapted to measure a distance between the feeding connector and an electrical connector and to determine the arrangement information based on the measured distance. In particular, the arrangement determining unit can be adapted to measure the distance between the feeding connector and a respective electrical connector for each electrical connector connected to the electrical conductor and to determine for each electrical connector its relative position, which is the position of the respective electrical connector relative to the other electrical connectors, on the electrical conductor as the arrangement information based on the measured distances. For instance, the arrangement information can be that a certain electrical connector is at the sixth position out of twelve electrical connectors, wherein this arrangement information can be sent to the respective electrical connector which can indicate this information.

In an embodiment, the arrangement determining unit is adapted to use sound waves for determining the distance. The sound waves can be used in the electrical conductor and/or in the air. In an embodiment, also a vibration of the electrical conductor can be used.

Preferably, the identities of devices like their communication protocol identifiers, for instance, IEEE addresses, are linked to their locations.

The above described techniques for determining the arrangement information can be performed by one or several electrical connectors, the feeding connector or by both, wherein in the latter case both, i.e. the one or several electrical connectors on the one side and the feeding connector on the other side, cooperate for performing the corresponding methods and are preferentially adapted to communicate with each other.

In a further aspect of the present invention a method for providing arrangement information regarding an electrical connector as defined in claim 1 for connecting an electrical device with an electrical conductor for powering the electrical device with DC voltage is presented, wherein the method includes the steps of providing arrangement information being information about the arrangement of the electrical connector on the electrical conductor, and indicating the determined arrangement information by an indicator.

In a further aspect of the present invention a computer program for providing arrangement information regarding an electrical connector as defined in claim 1 for connecting an electrical device with an electrical conductor for powering the electrical device with DC voltage is presented, wherein the computer program comprises program code means for causing the electrical connector to carry out the steps of the method for providing arrangement information as defined in claim 14, when the computer program is run on a computer controlling the electrical connector.

It shall be understood that the electrical connector of claim 1, the electrical device of claim 12, the feeding connector of claim 13, the method of claim 14 and the computer program of claim 15 have similar and/or identical preferred embodiments, in particular, as defined in the dependent claims.

It shall be understood that a preferred embodiment of the invention can also be any combination of the dependent claims with the respective independent claim.

These and other aspects of the invention will be apparent from and elucidated with reference to the embodiments described hereinafter.

### BRIEF DESCRIPTION OF THE DRAWINGS

In the following drawings:

FIG. 1 shows schematically and exemplarily an embodiment of a DC power distribution system,

FIG. 2 shows schematically and exemplarily details of connections within the DC power distribution system,

FIG. 3 shows schematically and exemplarily an embodiment of an electrical connector,

FIG. 4 shows schematically and exemplarily an embodiment of a feeding connector,

FIG. 5 shows schematically and exemplarily electrical connections within another DC power distribution system,

FIG. 6 shows schematically and exemplarily a further embodiment of an electrical connector,

FIG. 7 shows schematically and exemplarily a further embodiment of a feeding connector, and

FIG. 8 shows a flowchart exemplarily illustrating an embodiment of a method for providing arrangement information regarding an electrical connector for connecting an electrical device with an electrical conductor for powering the electrical device with DC voltage.

### DETAILED DESCRIPTION OF EMBODIMENTS

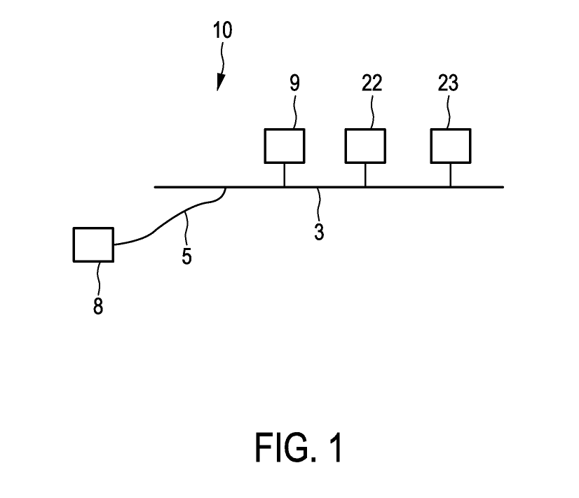

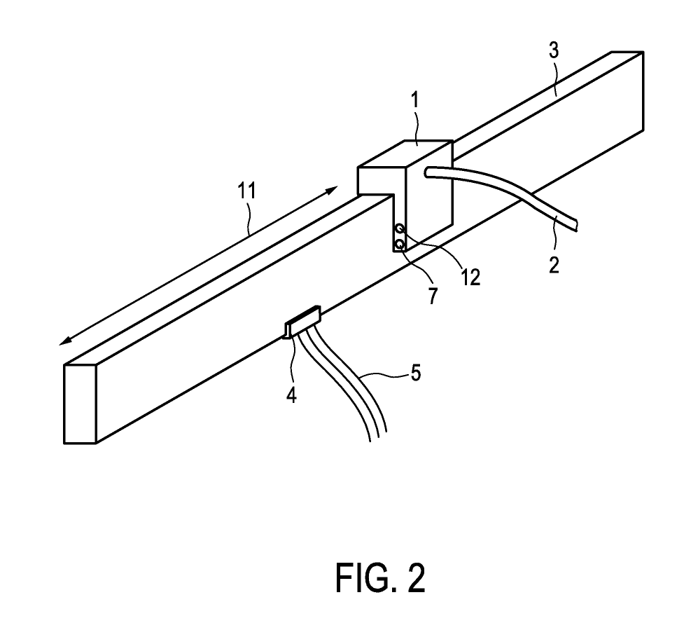

FIG. 1 shows schematically and exemplarily a DC power distribution system comprising a DC voltage source 8 being connected to an electrical conductor 3 via a cable 5, and electrical devices 9, 22, 23 like lamps, sensors et cetera being also connected to the electrical conductor 3. The DC power distribution system 10 can comprise many electrical devices of which three are exemplarily shown in FIG. 1. The connections for one electrical device 9 are exemplarily and schematically shown in more detail in FIG. 2.

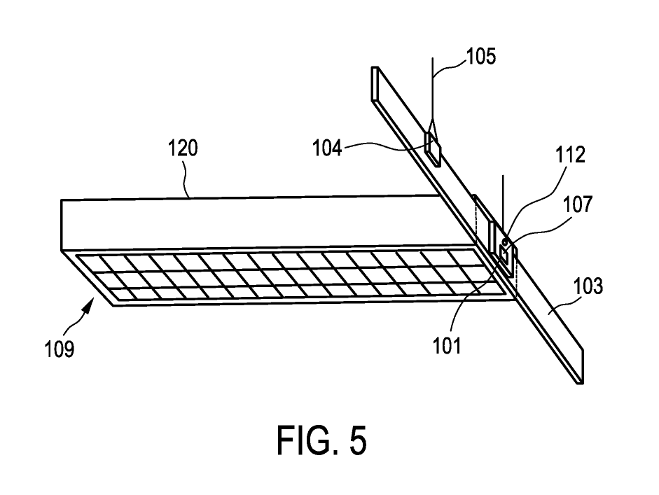

The cable 5 is electrically connected to the electrical conductor 3 via a feed connector 4, and the electrical device 9 is connected to the electrical conductor 3 via an electrical connector 1 and a further cable 2. In this embodiment, the feed connector 4 is located at one third of the length of the electrical conductor 3. The electrical connector 1 is located on the electrical conductor 3 with a distance 11 from an end of the electrical conductor 3. The electrical connector 1 can be attached via the cable 2 to the electrical device 9 as shown in FIG. 2, or the electrical connector 1 can be integrated with an electrical device as will be explained further below with reference to FIG. 5, wherein the electrical conductor 3 is a power rail and the connections can be, for instance, with an internal or external bus bar of the power rail.

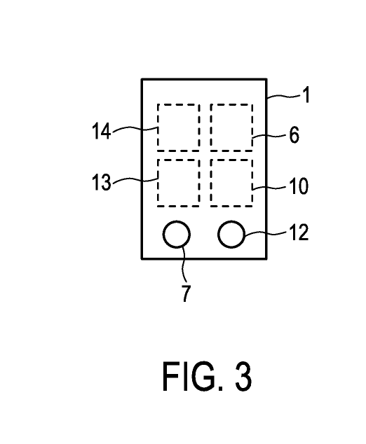

The electrical connector 1 comprises an arrangement information providing unit 6 for determining arrangement information being information about the arrangement of the electrical connector on the electrical conductor and an indicator 7 for indicating the provided arrangement information as schematically and exemplarily shown in FIG. 3.

In this embodiment, the arrangement information providing unit 6 is adapted to provide the location of the electrical connector on the electrical conductor as the arrangement information. Moreover, the arrangement information providing unit 6 is adapted to provide commissioning information as the arrangement information, wherein the commissioning information includes a number assigned to the electrical connector. The number may be regarded as being a commissioning number preferentially indicating the position of the respective electrical connector 1 on the electrical conductor 3 in a sequence of electrical connectors. For instance, the number can indicate that the respective electrical connector is at the sixth position in a sequence of twelve electrical connectors. Furthermore, the arrangement information providing unit 6 can be adapted to determine a power loss and to provide the arrangement information based on the determined power loss, wherein, if the power losses are larger than a predefined threshold, the arrangement information indicates that the electrical connector should be moved towards the feeding connector 4 connecting the electrical conductor 3 with the DC voltage source 8. Thus, the indicator 7 can reveal information like this load, i.e. this electrical device 9, will introduce a lot of losses in the electrical conductor 3, move it towards the feeding connector 4, in order to reduce the losses by decreasing the distance to the feeding connector 4.

The indicator 7 is adapted to optically and/or acoustically indicate the arrangement information. For instance, the indicator 7 can comprise one or several light emitting diodes for indicating the arrangement information by using colors. In particular, a blinking can be used for indicating the position of the current electrical connector 1 within a sequence of electrical connectors on the electrical conductor 3. The number of blinking signals can indicate the number counted from the feeding connector 4, or the position within the sequence can be indicated by using, for instance, green blinking for numbering information, long blinks for left, short blinks for right, i.e. it can be indicated that, for example, on the left side of the current electrical connector are five electrical connectors and on the right side are six electrical connectors such that the present electrical connector is at the sixth position out of twelve. For indicating whether the electrical connector 1 should be moved towards the feeding connector 4 a light in a certain color can be shown. For instance, a yellow blinking light can indicate that the electrical connector 1 should be moved, wherein the faster the blinking the more losses. Also other colors, blinking schemes, intuitive signals like a running light emitting diode pattern with a running light emitting diode dot “running” in the direction in which the electrical connector should be moved for reducing losses, et cetera can be used for indicating the arrangement information.

The arrangement information providing unit 6 is preferentially an arrangement information determining unit for determining the arrangement information. It can comprise a correspondingly adapted electrical circuit.

The arrangement information providing unit 6 can be adapted to emit an acoustical signal and measure the time/strength of the response signals, whereby the response signals are either reflections caused by the end of the electrical conductor 3, in particular, of the bus bar, or acoustical signals actively generated by another electrical or feeding connector on the electrical conductor 3. The differentiation between the reflections from the end of the electrical conductor 3 and the reflections from another electrical or feeding connector can be done by the arrangement providing unit 6 by estimating the strength of the received signal and/or by using another frequency for the response signal. Furthermore, different frequencies can be used by different connectors, for example, depending on their type or role, for instance, load connector versus power connector/feed, and/or depending on their location on the electrical conductor. Some or all connectors may participate, for instance, only the closest connector to the newly added connector, only the feed connector, all connectors according to a given timing and order. The time and/or strength of the response signals can directly be related to the respective distances, thereby allowing the arrangement providing unit 6 to determine the location of the current electrical connector on the electrical conductor and further arrangement information like the position of the current electrical connector within a sequence of electrical connectors. Thus, in an embodiment the arrangement information providing unit 6 counts the responses and measures the times of their arrival and thus determines the number of other devices on the same electrical conductor 3 and its own respective position.

In particular, the arrangement information providing unit 6 can be adapted to determine the distance to the ends of the electrical conductor 3 by receiving the reflected original acoustical signal and to determine the distance to the feeding connector 4, for instance, by receiving a repeated signal at a defined frequency from the feeding connector 4. This information, augmented by analogous information for other connectors on the same electrical conductor 3, which may be received from the other connectors via communications means or which may be determined by the current electrical connector 1, can subsequently be used by the arrangement information providing unit 6 to determine the order of connectors on the electrical conductor 3. This determination of the arrangement information can also be performed by another unit, in particular, on the same or another electrical conductor, like a corresponding unit of the feeding connector 4, a handheld unit et cetera, and sent to the arrangement information providing unit 6, wherein the arrangement information providing unit 6 can receive the arrangement information and the indicator 7 can indicate this information.

The arrangement information providing unit 6 can also be adapted to determine the distance to, for instance, an end of the electrical conductor 3 and to sent this distance together with an unique identifier to another unit gathering corresponding distance information and respective unique identifiers from all other electrical connectors on the electrical conductor 3. This other unit can then use this distance information and the identifiers for determining the sequence of the electrical conductors on the electrical conductor 3, wherein to each electrical connector a corresponding position within the sequence can be sent. This position is then received by the respective arrangement information providing unit 6 and indicated by the indicator 7. The other unit gathering the information can be regarded as being a controller unit located in, for instance, the DC voltage source, the feeding connector, or another device.

Moreover, having calibrated measurements at the connectors measuring the voltage that will be dropping when going from feed towards farthest connector can be another technique for detecting the respective position. In this case communication between different connectors and/or loads is preferentially used. Furthermore, the arrangement information providing unit can check, via communication means, if the other electrical devices connected to the electrical conductor are operational, drawing their maximum power, their operational characteristics, for instance, their time of usage, their power consumption characteristics, for example, inrush currents, et cetera.

The power losses can be determined by using different techniques, which may be performed by the arrangement information providing unit 6 or by an additional unit, which sends the power losses to the arrangement information providing unit 6. For instance, the voltage can be measured at multiple locations on the electrical conductor 3, for instance, at the feeding connector 4 and at the electrical connector 1. For example, the feeding connector 4 can measure the voltage at the feeding connector 4 and the electrical connector 1 can measure the voltage at the electrical connector 1, wherein the feeding connector 4 can send the measured voltage to the electrical connector 1, in order to allow the arrangement information providing 6 unit to determine the power losses associated with the actual location of the electrical connector 1. Also the current through the electrical connector can be measured for determining the power losses. If the power losses are larger than a predefined threshold, it can be indicated that the respective electrical conductor should be moved towards the feeding connector.

Alternatively or in addition, the voltage level at the electrical connector 1 can be measured when the newly connected load, i.e. the electrical device, is switched on. If the level is very near to low voltage margin as a result of the new load, the drop is obviously in the electrical conductor, in particular, in the bar, and cabling towards the power supply. Thus, a mechanism can measure voltage at off condition, than switch on, measure again and, if the step is big and the voltage is near low boundary, then indicate. In particular, in an embodiment the arrangement information providing unit 6 can be adapted to measure the voltage at an off condition, i.e. at a condition where the electrical device 9 is switched off, and at an on condition, i.e. at a condition where the electrical device 9 is switched on, and to compare these two voltages, wherein, if the voltage difference is larger than a predefined threshold and near a low boundary, the power losses are too large and it can be indicated that the electrical connector should be moved towards the feeding connector.

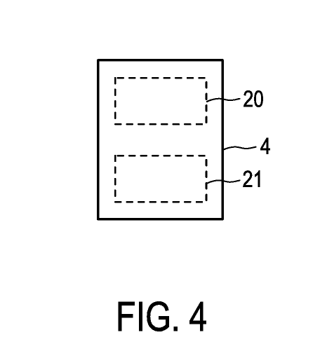

The arrangement information providing unit 6 can also be adapted to receive the arrangement information or to receive information, which is usable by the arrangement information providing unit 6 for determining the arrangement information, over a wired or wireless data connection. For instance, the arrangement information providing unit can be adapted to receive commissioning number information from a feeding connector for connecting the electrical conductor with a DC voltage source for feeding the electrical conductor with the DC voltage. Such an active feeding connector will in the following be described with reference to FIG. 4.

The feeding connector 4 schematically and exemplarily shown in FIG. 4 comprises an arrangement determining unit 20 for determining arrangement information for determining information about an arrangement of electrical connectors connected to the electrical conductor 3 and a sending unit 21 for sending the arrangement information to the electrical connector 1 for allowing the electrical connector 1 to indicate the arrangement information determined by the feeding connector 4. The arrangement determining unit 20 can be adapted to measure a distance between the feeding connector 4 and the electrical connector 1 and to determine the arrangement information based on the measured distance. In particular, the arrangement determining unit 20 can be adapted to measure the distance between the feeding connector 4 and a respective electrical connector for each electrical connector connected to the electrical conductor 3 and to determine for each electrical connector its relative position, which is the position of the respective electrical connector relative to the other electrical connectors, on the electrical conductor as the arrangement information based on the measured distances. For instance, the arrangement information can be that a certain electrical connector is at the sixth position out of twelve electrical connectors, wherein this arrangement information can be sent to the respective electrical connector which can indicate this information. In an embodiment, the arrangement determining unit is adapted to use sound waves for determining the distance. The sound waves can be used in the electrical conductor and/or in the air. In another embodiment, also a vibration of the electrical conductor can be used.

The above described techniques for determining the arrangement information can be performed by one or several electrical connectors, the feeding connector or by both, wherein in the latter case both, i.e. the one or several electrical connectors on the one side and the feeding connector on the other side, can cooperate for performing the corresponding methods and are preferentially adapted to communicate with each other.

In this embodiment, the electrical connector 1 further comprises an internal power supply 10 for supplying power to the arrangement information providing unit 6 and the indicator 7. The internal power supply is, for instance, a battery, a capacitor, et cetera. This allows providing the arrangement information and indicating the arrangement information, while there is no voltage on the power rail 3.

Moreover, the electrical connector 1 comprises an input unit 12 for allowing a user to input a request for providing, in particular, determining, and indicating the arrangement information. In this embodiment, the input unit 12 comprises a push button, wherein the electrical connector 1 is adapted to provide, in particular, determine, and indicate the arrangement information, if the push button 12 is pressed. Thus, the checks may be performed and the resulting arrangement information may be indicated on request, but not necessarily constantly. However, the arrangement information providing unit 6 and the indicator 7 can also be adapted such that selected checks and/or selected indications can be triggered automatically by certain conditions discovered during operation like a bus bar overload, which may occur, if another electrical device is added to the electrical conductor 3. In particular, the electrical connector 1 can further comprise an assignments providing unit 13 for providing assignments between a) at least one of determination procedures for determining arrangement information and indication procedures for indicating arrangement information and b) conditions, and a condition providing unit 14 for providing an actual condition, wherein at least one of the arrangement information providing unit 6 and the indicator 7 is adapted to perform a providing procedure, in particular, a determination procedure, and an indication procedure, respectively, in accordance with the provided actual condition and the provided assignments. The assignments providing unit 13 can be a storing unit in which predefined assignments are stored already, or a receiving unit for receiving the assignments via a wired or wireless data connection. The condition providing unit 14 can be a measuring unit for measuring the respective actual condition. The condition is, for example, an overload condition at the electrical conductor 3 to which the electrical connector 1 is connected. The condition providing unit 14 can be integrated with the arrangement information providing unit 6 such that the same unit, in particular, the same electrical circuit, is used for providing the arrangement information and for providing the actual condition. In an embodiment, the assignments define which arrangement information has to be determined by the arrangement information providing unit 6 and/or which arrangement information has to be indicated by the indicator 7, if the condition providing unit 14 determines an overload condition. The arrangement information providing unit and/or the indicator may be adapted to further process and/or store the provided arrangement information. Moreover, the arrangement information providing unit and/or the indicator may be adapted to send the provided arrangement information to another unit like the electrical device, if already connected.

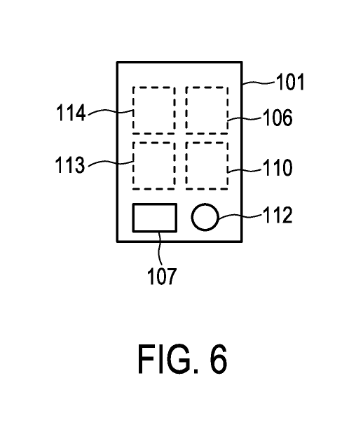

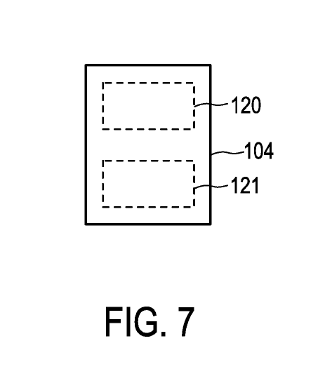

FIG. 5 shows schematically and exemplarily a further embodiment of an electrical connector 101 for connecting an electrical device to an electrical conductor 103 for powering the electrical device with DC voltage. A DC voltage source is electrically connected to the electrical conductor 103 via a cable 105 and a feed connector 104. The electrical conductor 103, the feed connector 104, the cable 105 and the DC voltage source are similar to the electrical conductor 3, the feed connector 4, the cable 5 and the DC voltage source 8 described above with reference to FIGS. 1 and 2. Moreover, also in this embodiment the electrical connector comprises an arrangement information providing unit 106, an indicator 107, an internal power supply like a battery 110, an input unit 112, an assignments providing unit 113 and a condition providing unit 114 as schematically and exemplarily shown in FIG. 6. Furthermore, also the feeding connector 104 comprises an arrangement determining unit 120 and a sending unit 121 as schematically and exemplarily shown in FIG. 7. These elements of the electrical connector 101 and the feeding connector 104 are similar to the corresponding elements of the electrical connector 1 and the feeding connector 4, respectively, described above with reference to FIGS. 2 to 4.

However, in this embodiment the electrical connector 101 is not connected with the electrical device 109 via a cable, but the electrical connector 101 is integrated into the electrical device 109 being, in this embodiment, a lamp. In particular, the electrical connector 101 is integrated into the housing 120 of the lamp 109. For instance, the electrical connector 101 can be mounted to at least one side of the housing 120 of the lamp 109, wherein preferentially electrical conductors like electrical wires are arranged within the electrical connector 101 such that the DC voltage applied to the electrical conductor 103 is applied to the lamp 109.

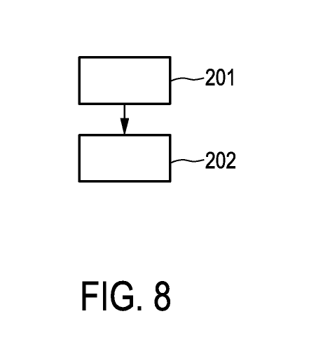

In the following a method for providing arrangement information regarding an electrical connector for connecting an electrical device with an electrical conductor for powering the electrical device with DC voltage will exemplarily be described with reference to a flowchart shown in FIG. 8.

In step 201, arrangement information being information about the arrangement of the electrical connector on the electrical conductor is provided. For instance, the arrangement information providing unit of the electrical connector and/or the arrangement information determining unit of the feeding connector can determine the location of the respective connector, numbering, in particular, commissioning numbers, whether the respective electrical connector should be moved towards the feeding connector due to losses, et cetera as arrangement information. In step 202, the determined arrangement information is indicated by an indicator by using, for example, blinking light emitting diodes.

Although in the above described embodiments the electrical device is, for example, a lamp like a fluorescent lamp, a light emitting diode, et cetera, the electrical device can also be another load like a sensor, a game console, et cetera. In an embodiment, the electrical device is a light emitting lighting load with a minimum of hardware, wherein the electrical device may not comprise a rectifier bridge.

The electrical conductors are preferentially electrical conductors in accordance with the EMerge standard. These electrical conductors are preferentially power rails, which can also be called bus bars.

The DC power distribution systems described above with reference to FIGS. 1 to 7 are preferentially low voltage DC power distribution systems, which are adapted to be used in commercial buildings. For instance, they can be low voltage DC ceiling grid systems for distributing the DC voltage among electrical devices located at the ceiling like lamps or sensors. The different components of the DC power distribution systems are preferentially in line with the EMerge standard. In particular, the DC power distribution systems comprise preferentially a power rail being standardized in accordance with the EMerge standard, wherein loads like lighting fixtures are attached to the power rail, to be powered and, if at the ceiling, to be fixed to a ceiling grid.

The power rails can carry a maximum load in terms of power dissipation, which is preferentially defined by the EMerge standard and safety regulations. However, generally it is still possible to physically attach loads, i.e. electrical devices, to the power rail, which total current/voltage/power consumption would exceed the specified maximum load. Safety features are in place, in order to shut down the power rail in such a case, but it is better to prevent the system for shut down after installation. Thus, the electrical connectors and/or the feeding connectors can be adapted to determine whether the total current/voltage/power consumption would exceed the specified maximum load and to indicate this to an installer.

The electrical devices to be attached to the electrical conductor can be polarity sensitive. In the prior art there is mechanically no safety feature in place, neither on the power rail nor on the electrical connector, which could prevent loads to be connected in the wrong manner in terms of polarity. Therefore, the electrical connector and/or feeding connector may be adapted to allow performing a polarity check and indicating whether the polarity is correct or not.

The electrical connector and/or the feeding connectors can additionally be adapted to make immediately clear to installers, if hardware is installed correctly, wherein the loads power-rail connector, i.e. the respective electrical connector, is equipped with feedback means, i.e. an indicator, which may comprise light emitting diodes or other optical or acoustical indication means, in order to—inter alia—indicate polarity correctness and/or power rail status to the installer.

Although in the above described embodiments the arrangement information providing unit and the indicator are adapted to determine and indicate certain arrangement information, in other embodiments the arrangement information providing unit and the indicator can also be adapted to provide other arrangement information about the arrangement of the electrical connector on the electrical conductor. In particular, the arrangement information providing unit and the indicator can be adapted to provide and indicate different kinds of arrangement information, in particular, as described above.

Inside the respective electrical connector a circuit can be present, i.e. an arrangement information providing unit, which checks and can reveal information on, for instance, the location of the respective electrical connector 1 on the power rail 3 and/or numbering (commissioning). In particular, if an installer connects a load, i.e. an electrical device, by means of an electrical connector 1 an indicator can reveal information like: This load will introduce lots of losses in the power rail 3, move it towards feed 4, in order to reduce losses by decreasing distance 11 (FIG. 2), or you are connector number six on this power rail out of twelve connectors in total.

For position check on the power rail communication can be used. In particular, a communication device can be built into the feed, i.e. the feeding connector 4, 104, in order to measure the distance between the electrical connector 1, 101 and the feed 4, 104. The feed 4, 104 can also be adapted to gather information about other loads, other electrical devices, connected to the power rail 3, 103, in order to give, for instance, proper feedback on maximum power indication to the indicator.

The indicator can be adapted provide a green blinking for numbering information, long blinks for left, short blinks for right, in order to indicate the position of the respective electrical connector. A green/yellow blinking can be provided, in order to indicate that the electrical connector should be moved for optimization, i.e. for reducing losses, wherein the faster it blinks, the more losses. The indicator can also be adapted to indicate the arrangement information and optional further information by using other optical and/or acoustical schemes. In particular, indication can also be done by sound, wherein in the above examples the different colors can be replaced by different tones.

Sound waves can be used to measure the distance between the feed 4, 104 and the electrical connector 1, 101 like used for car parking. The sound wave propagation is a measure for distance, wherein preferentially second order waves, third order waves and other waves caused by reflections are neglected. The technique can be applied here for a different purpose. Instead of or in addition to a sound measurement also power-line communication (PLC) can be used to communicate and measure distances.

Since, in an embodiment, the feed 4, 104 knows about all electrical connectors and power ratings connected to its rail at certain distances, it can count and automatically assign numbers, in particular, rail number and/or connector number, to every electrical connector attached to it. This means commissioning of the total system can be solved.

Other variations to the disclosed embodiments can be understood and effected by those skilled in the art in practicing the claimed invention, from a study of the drawings, the disclosure, and the appended claims.

In the claims, the word “comprising” does not exclude other elements or steps, and the indefinite article “a” or “an” does not exclude a plurality.

A single unit or device may fulfill the functions of several items recited in the claims. The mere fact that certain measures are recited in mutually different dependent claims does not indicate that a combination of these measures cannot be used to advantage.

Operations like determining arrangement information, indicating the determined arrangement information, determining an actual condition, triggering certain actions depending on an actual condition, et cetera performed by one or several units or devices can be performed by any other number of units or devices. These operations and/or the control of the electrical connector and/or the feeding connector in accordance with the method for providing arrangement information can be implemented as program code means of a computer program and/or as dedicated hardware.

A computer program may be stored/distributed on a suitable medium, such as an optical storage medium or a solid-state medium, supplied together with or as part of other hardware, but may also be distributed in other forms, such as via the Internet or other wired or wireless telecommunication systems.

Any reference signs in the claims should not be construed as limiting the scope.

1. An electrical connector for connecting an electrical device to an electrical conductor for powering the electrical device with DC voltage, the electrical connector comprising:
an arrangement information providing unit for determining arrangement information being information about the arrangement of the electrical connector on the electrical conductor,
an indicator for indicating the provided arrangement information, wherein
the arrangement information providing unit is configured to determine a power loss and to provide the arrangement information based on the determined power loss, and wherein, if the power losses are larger than a predefined threshold, the arrangement information indicates that the electrical connector is to be moved towards a feeding connector connecting the electrical conductor with a DC voltage source.

2. The electrical connector as defined in claim 1, wherein the arrangement information providing unit is adapted to provide the location of the electrical connector on the electrical conductor as the arrangement information.

3. The electrical connector as defined in claim 1, wherein the arrangement information providing unit is adapted to provide commissioning information as the arrangement information.

4. The electrical connector as defined in claim 3, wherein the commissioning information includes a number assigned to the electrical connector.

5. (canceled)

6. (canceled)

7. The electrical connector as defined in claim 1, wherein the arrangement information providing unit is an arrangement information determining unit for determining the arrangement information.

8. The electrical connector as defined in claim 1, wherein the arrangement information providing unit is adapted to receive the arrangement information or to receive information, which is usable by the arrangement information providing unit for determining the arrangement information, over a wired or wireless data connection.

9. The electrical connector as defined in claim 1, wherein the electrical connector comprises a power supply for supplying power to the arrangement information providing unit and the indicator.

10. The electrical connector as defined in claim 1, wherein the electrical connector comprises an input unit for allowing a user to input a request for determining and indicating the arrangement information.

11. The electrical connector as defined in claim 1, wherein the electrical connector further comprises:
an assignments providing unit for providing assignments between a) at least one of determination procedures for determining arrangement information and indication procedures for indicating arrangement information and b) conditions, and
a condition providing unit for providing an actual condition, wherein at least one of the arrangement information providing unit and the indicator are adapted to perform a determination procedure and an indication procedure, respectively, in accordance with the provided actual condition and the provided assignments.

12. An electrical device to be electrically connected with an electrical conductor to be powered by DC voltage, wherein the electrical device comprises the electrical connector as defined in claim 1.

13. A feeding connector for connecting an electrical conductor with a DC voltage source for feeding the electrical conductor with DC voltage, wherein the feeding connector comprises:
an arrangement determining unit for determining arrangement information for determining information about an arrangement of electrical connectors connected to the electrical conductor, wherein the arrangement information providing unit is configured to determine a power loss and to provide the arrangement information based on the determined power loss, and wherein, if the power losses are larger than a predefined threshold, the arrangement information indicates that the electrical connector is to be moved towards a feeding connector connecting the electrical conductor with a DC voltage source, and
a sending unit for sending the arrangement information to an electrical connector for allowing the electrical connector to indicate the arrangement information.

14. A method for providing arrangement information regarding an electrical connector as defined in claim 1 for connecting an electrical device with an electrical conductor for powering the electrical device with DC voltage, the method including the steps of:
providing arrangement information being information about the arrangement of the electrical connector on the electrical conductor,
determining a power loss and providing the arrangement information based on the determined power loss, wherein, if the power losses are larger than a predefined threshold, the arrangement information indicates that the electrical connector is to be moved towards a feeding connector connecting the electrical conductor with a DC voltage source, and
indicating the determined arrangement information by an indicator.

15. A non-transitory computer readable medium for providing arrangement information regarding an electrical connector as defined in claim 1 for connecting an electrical device with an electrical conductor for powering the electrical device with DC voltage, the computer readable medium comprising sequences of instructions stored thereon for causing at least one processor to perform the steps of:
providing arrangement information being information about the arrangement of the electrical connector on the electrical conductor,
determining a power loss and providing the arrangement information based on the determined power loss, wherein, if the power losses are larger than a predefined threshold, the arrangement information indicates that the electrical connector is to be moved towards a feeding connector connecting the electrical conductor with a DC voltage source, and
indicating the determined arrangement information by an indicator.
